(19) United States
(12) Patent Application Publication
(10) Pub. No.: US 2026/0113998 A1
(43) Pub. Date: Apr. 23, 2026

(54) FIN ISOLATION STRUCTURES FORMED AFTER GATE METALLIZATION

(71) Applicant: Intel Corporation, Santa Clara, CA (US)

(72) Inventors: Leonard P. GULER, Hillsboro, OR (US); Tsuan-Chung CHANG, Portland, OR (US); Tahir GHANI, Portland, OR (US); Robert JOACHIM, Beaverton, OR (US); Sean PURSEL, Tigard, OR (US)

(21) Appl. No.: 19/427,407

(22) Filed: Dec. 19, 2025

Related U.S. Application Data
(63) Continuation of application No. 17/685,632, filed on Mar. 3, 2022.

(51) Int. Cl. H10D 62/10; H10D 30/67; H10D 84/83

(52) U.S. Cl. CPC H10D 62/121; H10D 30/6713; H10D 30/6735; H10D 30/6757; H10D 62/115; H10D 84/834

(57) ABSTRACT

Techniques are provided herein to form fin cut structures, or fin isolation structures, after the metal gate has been formed. In an example, a row of semiconductor devices each include a semiconductor region extending in a first direction between a source region and a drain region, and a gate structure extending in a second direction over the semiconductor regions of each neighboring semiconductor device along the row. A fin cut structure that includes a dielectric material interrupts the gate structure and replaces the semiconductor region of one of the semiconductor devices, effectively cutting through the length of the semiconductor device fin (or nanoribbons). The gate structure is formed first followed by removing a portion of the gate structure and removing the semiconductor region of one of the semiconductor devices to form the fin cut structure. In this way, the fin cut structure does not interfere when forming the gate structure.

### CROSS-REFERENCE TO RELATED APPLICATIONS

This application is a continuation of U.S. patent application Ser. No. 17/685,632, filed on Mar. 3, 2022, the entire contents of which is hereby incorporated by reference herein.

### FIELD OF THE DISCLOSURE

The present disclosure relates to integrated circuits, and more particularly, to fin cut structures and gate cut structures.

### BACKGROUND

As integrated circuits continue to scale downward in size, a number of challenges arise. For instance, reducing the size of memory and logic cells is becoming increasingly more difficult, particularly given competing interests in a relatively small amount of space. For instance, on one hand, certain processes like the formation of metal gate layers can be disrupted by the presence of other structures, like fin cut structures. On the other hand, such fin cut structures may be necessary to form a desired logic or memory circuit. Accordingly, there remain a number of non-trivial challenges with respect to the formation of semiconductor devices in memory or logic cells.

### BRIEF DESCRIPTION OF THE DRAWINGS

FIG. 1 is an isometric view of an integrated circuit structure that includes a gate cut structure and a fin cut structure, in accordance with an embodiment of the present disclosure.

FIGS. 2A and 2B are cross-sectional and plan views, respectively, that illustrate one stage in an example process for forming an integrated circuit configured with a fin cut structure, in accordance with an embodiment of the present disclosure.

FIGS. 3A and 3B are cross-sectional and plan views, respectively, that illustrate another stage in the example process for forming an integrated circuit configured with a fin cut structure, in accordance with an embodiment of the present disclosure.

FIGS. 4A and 4B are cross-sectional and plan views, respectively, that illustrate another stage in the example process for forming an integrated circuit configured with a fin cut structure, in accordance with an embodiment of the present disclosure.

FIGS. 5A and 5B are cross-sectional and plan views, respectively, that illustrate another stage in the example process for forming an integrated circuit configured with a fin cut structure, in accordance with an embodiment of the present disclosure.

FIGS. 6A and 6B are cross-sectional and plan views, respectively, that illustrate another stage in the example process for forming an integrated circuit configured with a fin cut structure, in accordance with an embodiment of the present disclosure.

FIGS. 7A and 7B are cross-sectional and plan views, respectively, that illustrate another stage in the example process for forming an integrated circuit configured with a fin cut structure, in accordance with an embodiment of the present disclosure.

FIGS. 8A and 8B are cross-sectional and plan views, respectively, that illustrate another stage in the example process for forming an integrated circuit configured with a fin cut structure, in accordance with an embodiment of the present disclosure.

FIGS. 9A and 9B are cross-sectional and plan views, respectively, that illustrate another stage in the example process for forming an integrated circuit configured with a fin cut structure, in accordance with an embodiment of the present disclosure.

FIG. 9C is a plan view that illustrates a stage in the example process for forming an integrated circuit configured with a fin cut structure in some more detail, in accordance with some embodiments of the present disclosure.

FIGS. 10A and 10B are cross-sectional and plan views, respectively, that illustrate another stage in the example process for forming an integrated circuit configured with a fin cut structure, in accordance with an embodiment of the present disclosure.

FIG. 11 illustrates a cross-section view of a chip package containing one or more semiconductor dies, in accordance with some embodiments of the present disclosure.

FIG. 12 is a flowchart of a fabrication process for a semiconductor device having a fin cut structure, in accordance with an embodiment of the present disclosure.

FIG. 13 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form fin cut structures, also referred to as fin isolation structures, after the metal gate has been formed. The techniques can be used in any number of integrated circuit applications and are particularly useful with respect to logic and memory cells, such as those cells that use finFETs or gate-all-around transistors (e.g., ribbonFETs and nanowire FETs), or other integrated circuit structures where fin isolation structures and temperature-sensitive structures such as gate structures co-exist on a common die. In an example, a row of semiconductor devices each include a semiconductor region extending in a first direction between a corresponding diffusion regions (e.g., source region and a drain region), and a gate structure extending in a second direction over the semiconductor regions of each neighboring semiconductor device along the row. A fin cut structure that includes a dielectric material interrupts the gate structure and also replaces the semiconductor region of one of the semiconductor devices. The semiconductor region can be, for example, a fin or one or more nanoribbons, nanowires or nanosheets, and the fin cut structure effectively cuts through the length of the fin (or nanoribbons, nanowires or nanosheets). According to an embodiment, the final gate structure is formed first followed by removing a portion of the gate structure and removing the semiconductor region of one of the semiconductor devices to form the fin cut structure. In this way, the fin cut structure does not interfere with the formation of the gate structure. Due to the timing of the operations, one or more of the metal gate layers of the gate structure will directly abut the fin cut structure (e.g., with no gate dielectric between the metal and the fin cut structure). Numerous variations and embodiments will be apparent in light of this disclosure.

### General Overview

As previously noted above, there remain a number of non-trivial challenges with respect to formation of various semiconductor structures. In more detail, the formation of the gate structure across multiple semiconductor devices involves numerous deposition processes of various materials, such as dielectric materials to make up the gate dielectric and various conductive materials like work-function metals to form gate layers over the gate dielectric. Such processes become challenging when various structures interrupt the area in which the gate structure is being formed. These structures may include fin cut structures, which may be used to isolate sections of a given semiconductor fin having several semiconductor devices formed along the fin. As used herein, the term fin is used to describe a body of semiconductor material(s) extending lengthwise in a given direction. The fin may have a traditional fin-like shape extending above a substrate, and may include a single layer or multiple layers such as in the case where the fin includes one or more nanowires, nanoribbons, or nanosheets of semiconductor material. In any such cases, the presence of a fin cut structure can cause problems when depositing the gate structure materials, especially for semiconductor devices adjacent to the fin cut structure.

Thus, and in accordance with an embodiment of the present disclosure, techniques are provided herein to form fin cut structures after the formation of the gate structure. A gate structure includes both one or more gate dielectric layers and one or more conductive gate layers formed over the semiconductor regions of one or more semiconductor devices. In some embodiments, the gate structure extends lengthwise along a given direction across multiple semiconductor regions of different semiconductor devices. Once the gate structure has been formed, the gate structure around one of the semiconductor devices may be removed (in one or more locations) using one or more different etching processes to selectively remove the dielectric layers and metal layers of the gate structure, followed by the selective removal of the exposed semiconductor region. Further etching may be performed through a dielectric layer beneath the semiconductor region and adjacent to a subfin portion of the semiconductor device. For example, and according to some such embodiments, a fin cut structure is formed within the resulting large recess through the gate structure and through the dielectric layer. Due to the relative order of the fabrication processes, one or more of the conductive gate layers of the gate structure directly abuts at least part of the fin cut structure. In some examples, it can be difficult to remove all of the gate structure during its etching process and so at least a portion of any of the conductive gate layers can exist between sides of the fin cut structure and sidewall spacers on either side of the gate structure. To avoid potential shorting issues between the collinear gate structures on either side of the fin cut structure, a gate cut structure may be formed directly adjacent to or at least near to (e.g., within 1-5 nm from) the fin cut structure.

According to an embodiment, an integrated circuit includes a semiconductor device having a subfin region and a first semiconductor region above the subfin region and extending in a first direction between a source region and a drain region, a dielectric layer adjacent to the subfin region, a gate structure with a gate layer comprising a conductive material, spacer layers on sidewalls of the gate structure, and an isolation structure between the spacer layers and interrupting the gate layer. The gate layer extends over the semiconductor region in a second direction different from the first direction. The isolation structure extends through at least a portion of the dielectric layer and directly abuts a second semiconductor region extending parallel to the first semiconductor region in the first direction. The conductive gate layer directly abuts at least a portion of the isolation structure.

According to another embodiment, an integrated circuit includes a semiconductor device having a subfin region and a first semiconductor region above the subfin region and extending in a first direction between a source region and a drain region, a dielectric layer adjacent to the subfin region, a gate structure with a gate layer comprising a conductive material, spacer layers on sidewalls of the gate structure, and an isolation structure between the spacer layers and interrupting the gate layer. The gate layer extends over the semiconductor region in a second direction different from the first direction. The isolation structure extends through at least a portion of the dielectric layer and directly abuts a second semiconductor region extending parallel to the first semiconductor region in the first direction. At least a portion of the conductive gate layer is present between a sidewall of the isolation structure and one of the spacer layers.

According to another embodiment, a method of forming an integrated circuit includes forming a first fin comprising first semiconductor material and a second fin comprising second semiconductor material, wherein the first fin and the second fin extend parallel to one another above a dielectric layer; forming a sacrificial gate layer over the first fin and the second fin and forming sidewall layers on sidewalls of the sacrificial gate layer; removing the sacrificial gate layer and forming a gate structure between the sidewall layers and over the first semiconductor material and the second semiconductor material; removing a portion of the gate structure around the second semiconductor material and removing the second semiconductor material from between the spacer layers to form a recess through the gate structure; and forming an isolation structure within the recess such that the isolation structure interrupts the gate structure.

The techniques can be used with any type of non-planar transistors, including finFETs (sometimes called double-gate transistors, or tri-gate transistors), or nanowire and nanoribbon transistors (sometimes called gate-all-around transistors), to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate a fin cut structure interrupting both a semiconductor fin (or other channel region) extending in a first direction and a gate structure extending between sidewall spacers in a second direction substantially orthogonal to the first direction. One or more conductive gate layers of the gate structure would be observed to directly abut the fin cut structure (e.g., no intervening dielectric layers). Furthermore, portions of the conductive gate layers may be present between sidewalls of the fin cut structure and the sidewall spacers. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

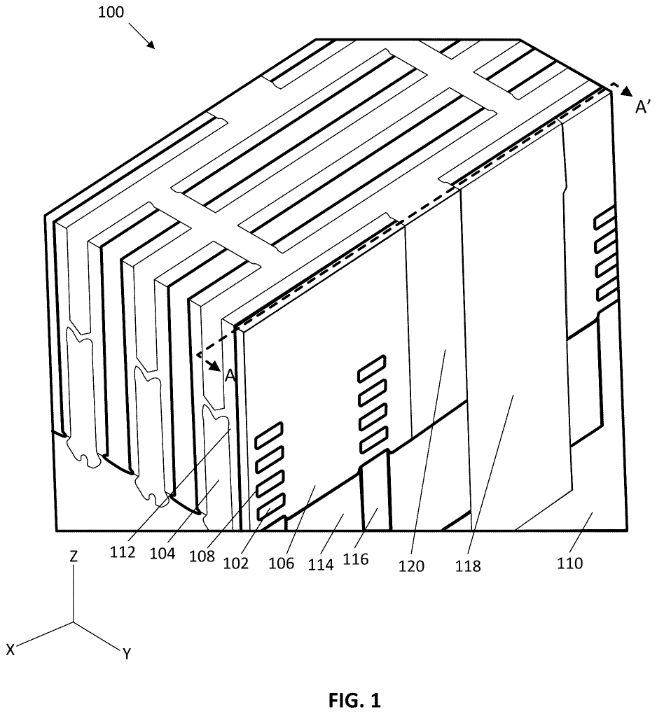

FIG. 1 is an isometric view of a portion of an integrated circuit 100 that includes various parallel semiconductor devices, in accordance with an embodiment of the present disclosure. Each of the semiconductor devices may be non-planar metal oxide semiconductor (MOS) transistors, such as tri-gate or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions).

Each semiconductor device includes one or more semiconductor regions, such as one or more nanoribbons 102 extending between epitaxial source or drain regions 104 in a first direction along the Y-axis. A gate structure that includes gate layer 106 and a gate dielectric layer 108 extends over the one or more semiconductor regions in a second direction (e.g. along the X-axis) to form the transistor gate. Gate layer 106 may represent any number of conductive layers (such as various work function metals) and gate dielectric layer 108 may represent any number of dielectric layers. A given gate structure may extend over the semiconductor regions of more than one semiconductor device. It should be noted that the one or more semiconductor regions of each device are not shown in the isometric view of FIG. 1 as they are covered by other material layers.

The semiconductor material used in each of the semiconductor devices may be formed from a semiconductor substrate 110. Substrate 110 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, substrate 110 is removed and replaced with one or more backside interconnect layers to form backside signal and power routing.

The one or more semiconductor regions of the devices may include fins that can be, for example, native to the substrate (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around process can then be carried out. Again, the alternating layers can be blanket deposited and then etched into fins or deposited into fin-shaped trenches.

Source or drain regions 104 may be formed at the ends of the one or more semiconductor regions (such as at the ends of nanoribbons 102) of each device, and thus may be aligned along the second direction from one another. According to some embodiments, source or drain regions 104 are epitaxial regions that are provided on the semiconductor regions in an etch-and-replace process. In other embodiments source or drain regions 104 could be, for example, implantation-doped native portions of the fins or substrate. Any semiconductor materials suitable for source or drain regions can be used (e.g., group IV and group III-V semiconductor materials). Source or drain regions 104 may include multiple layers such as liners and capping layers to improve contact resistance. In any such cases, the composition and doping of source or drain regions 104 may be the same or different, depending on the polarity of the transistors. Any number of source or drain configurations and materials can be used.

As noted above, a gate structure extends in the second direction over the one or more semiconductor regions of various devices and includes both gate layer 106 and gate dielectric 108. Gate layer 106 may include any sufficiently conductive material such as a metal, metal alloy, or doped polysilicon. In some embodiments, gate layer 106 includes one or more workfunction metals around the one or more semiconductor regions. In some embodiments, p-channel devices include a workfunction metal having titanium around its one or more semiconductor regions and n-channel devices include a workfunction metal having tungsten around its one or more semiconductor regions. Gate layer 106 may also include a fill metal or other conductive material around the workfunction metals to provide the whole gate electrode structure.

According to some embodiments, spacer structures 112 are present on the sidewalls of the gate structure and define a gate trench through which the gate structure is formed. Spacer structures 112 may include a suitable dielectric material such as silicon nitride or silicon oxynitride.

As can further be seen, a dielectric layer 114 extends across a bottom portion of the integrated circuit and adjacent to subfin 116 of each of the semiconductor devices, according to an embodiment. Dielectric layer 114 may include any suitable dielectric material such as silicon oxide. Dielectric layer 114 provides shallow trench isolation (STI) between adjacent semiconductor devices. According to some embodiments, subfin 116 is a portion of the corresponding semiconductor fin that remains after formation of the various transistors and may be formed from semiconductor substrate 110. Accordingly, subfin 116 may include the same semiconductor material as the one or more semiconductor regions of the semiconductor devices.

According to some embodiments, a fin cut structure 118 extends lengthwise in a third direction (e.g., along the z-axis) within the gate trench. Fin cut structure 118 may be provided to electrically isolate different transistors of the same fin extending lengthwise in the first direction. The portion of the fin that would have been viewable in FIG. 1 has been replaced with fin cut structure 118. In some embodiments, fin cut structure 118 further isolates portions of the gate structure from one another (e.g. interrupting the conductive gate layer).

Fin cut structure 118 may be any suitable dielectric material. In some embodiments, fin cut structure 118 is a low-K dielectric material. Some examples of low-K dielectrics include silicon oxide, silicon nitride, or silicon oxynitride. According to some embodiments, fin cut structure 118 extends below the bottom surface of the gate structure and through the subfin portion of the semiconductor device. In one example, fin cut structure 118 extends through an entire thickness of dielectric layer 114 to ensure that the entirety of the subfin portion has been removed from beneath fin cut structure 118.

According to some embodiments, the gate structure may be further interrupted by a gate cut structure 120. Gate cut structure 120 may be provided to redundantly isolate portions of the gate structure from one another in the event that there are some portions of gate layer 106 present along the longer sidewalls of fin cut structure 118. gate cut structure 120 may be formed from a sufficiently insulating material, such as a dielectric material. Example materials for gate cut structure 120 include silicon nitride, silicon oxide, or silicon oxynitride. In some embodiments, gate cut structure 120 is formed directly adjacent to fin cut structure 118 within the gate trench. According to some embodiments, gate cut structure 120 interrupts both the gate structure and also spacer structures 112 on either side of the gate structure. In some embodiments, gate cut structure 120 extends further beyond the edge of one or both spacer structures 112.

### Fabrication Methodology

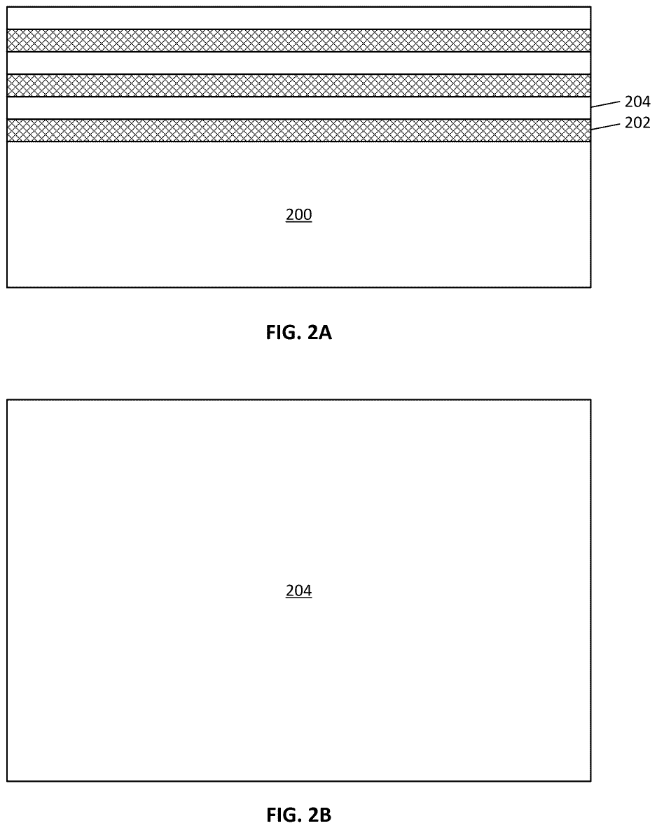

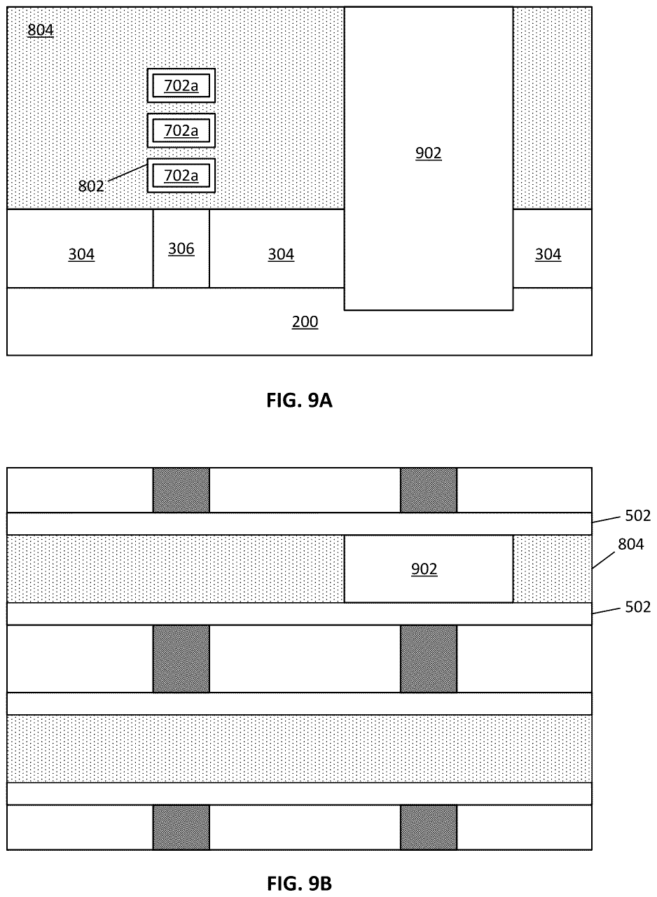

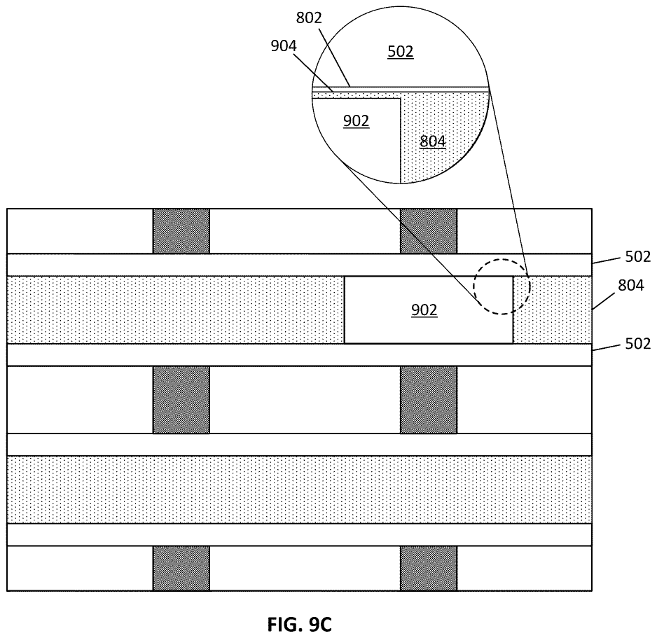

FIG. 2A-9A and 2B-9B are cross-sectional and plan views, respectively, that collectively illustrate an example process for forming an integrated circuit configured with a fin cut structure formed after the gate structure, in accordance with an embodiment of the present disclosure. FIGS. 2A-9A represent a cross-sectional view taken across plane A-A′ shown in FIG. 1. Each figure shows an example structure that results from the process flow up to that point in time, so the depicted structure evolves as the process flow continues, culminating in the structure shown in FIGS. 9A and 9B, which is similar to the structure shown in FIG. 1. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated. Figures sharing the same number (e.g., FIGS. 2A and 2B) illustrate different views of the structure at the same point in time during the process flow.

FIGS. 2A and 2B illustrate cross-sectional and plan views, respectively, of multiple material layers formed over a substrate, according to an embodiment of the present disclosure. Alternating material layers may be deposited over a substrate 200 including sacrificial layers 202 alternating with semiconductor layers 204. The alternating layers are used to form GAA transistor structures. Any number of alternating semiconductor layers 204 and sacrificial layers 202 may be deposited over substrate 200.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Each of sacrificial layers 202 and semiconductor layers 204 may be deposited using any known material deposition technique, such as chemical vapor deposition (CVD), plasma-enhanced chemical vapor deposition (PECVD), physical vapor deposition (PVD), or atomic layer deposition (ALD). FIG. 2B illustrates a plan view showing only the top-most deposited semiconductor layer 204, according to an embodiment.

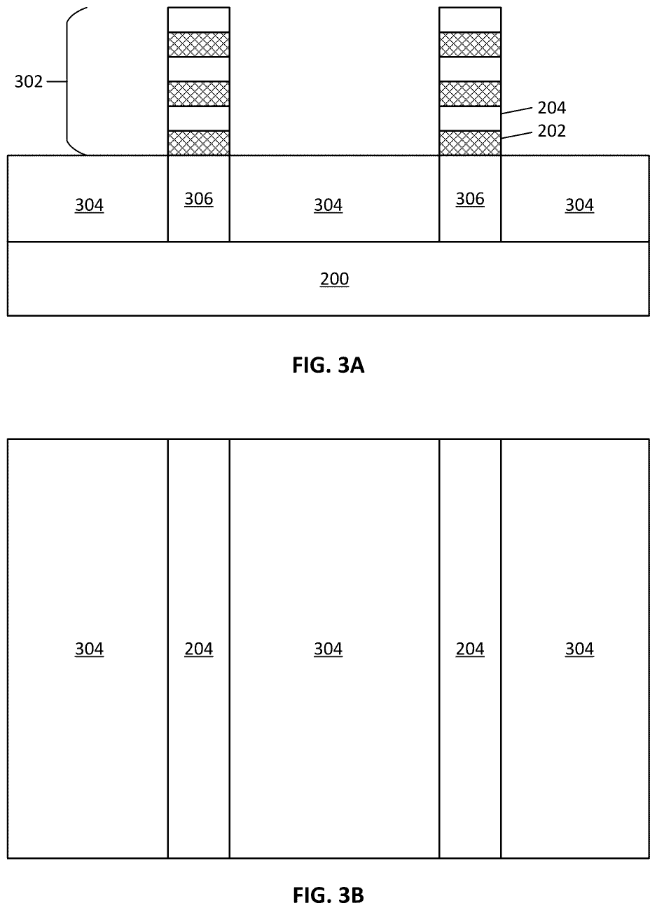

FIGS. 3A and 3B depict the cross-section and plan views of the structure shown in FIGS. 2A and 2B, respectively, following the formation of semiconductor fins extending above the substrate, according to an embodiment. Each of fins 302 may be lithographically patterned into parallel rows from the alternating layer stack of sacrificial layers 202 and semiconductor layers 204.

According to some embodiments, an anisotropic etching process through the layer stack continues into at least a portion of substrate 200. The etched portion of substrate 200 may be filled with a dielectric layer 304 that acts as shallow trench isolation (STI) between adjacent fins. Dielectric layer 304 may be any suitable dielectric material such as silicon oxide. Subfin regions 306 represent remaining portions of substrate 200 between dielectric layer 304, according to some embodiments. FIG. 3B illustrates how dielectric layer 304 extends along the entire length of each of the fins, according to some embodiments.

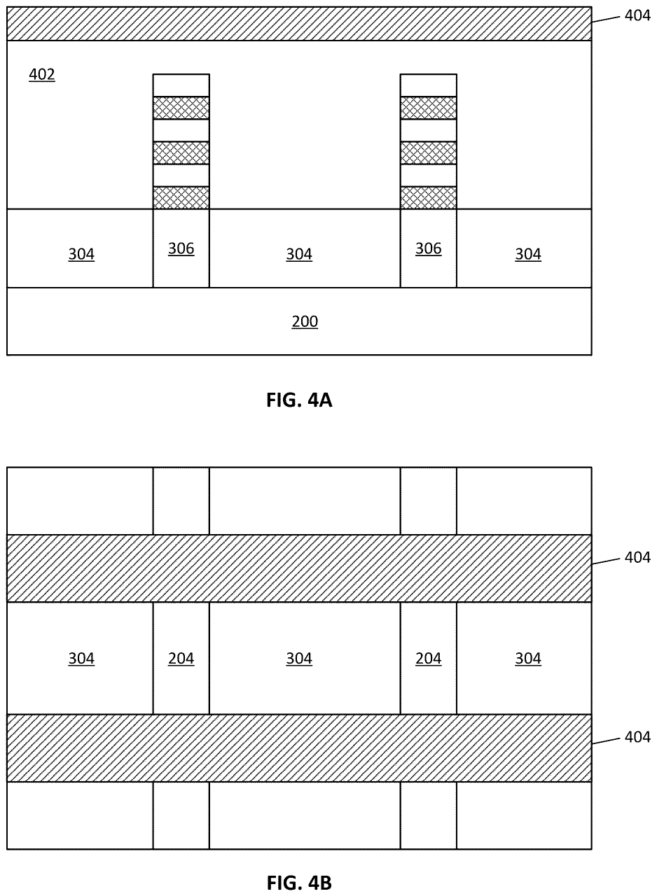

FIGS. 4A and 4B depict the cross-section and plan views of the structure shown in FIGS. 3A and 3B, respectively, following the formation of a sacrificial gate 402 beneath a corresponding gate masking layer 404, according to some embodiments. Gate masking layers 404 may be patterned in strips that extend orthogonally across each of the fins in order to form corresponding sacrificial gates 402 in strips beneath the gate masking layers 404. According to some embodiments, the sacrificial gate material is removed in all areas not protected by gate masking layers 404. Gate masking layer 404 may be any suitable hard mask material such as CHM or silicon nitride. Sacrificial gate 402 may be any suitable material that can be selectively removed without damaging the semiconductor material of the fins. In some examples, sacrificial gate 402 includes polysilicon.

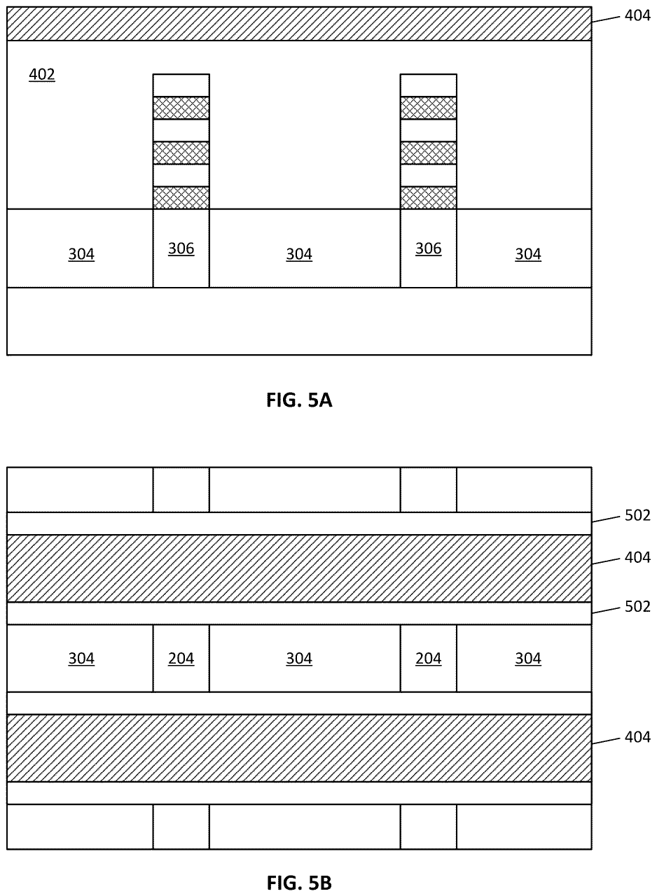

FIGS. 5A and 5B depict the cross-section and plan views of the structure shown in FIGS. 4A and 4B, respectively, following the formation of spacer structures 502, according to some embodiments. Spacer structures 502 may be formed along the sidewalls of gate masking layers 404 and the underlying sacrificial gates 402. Spacer structures 502 may be deposited and then etched back such that spacer structures 502 remain mostly only on sidewalls of any exposed structures. In the plan view of FIG. 5B, sidewall spacers may also be formed along sidewalls of the exposed fins between gate masking layers 404. Such sidewall spacers on the fins can be removed during later processing when forming the source or drain regions. According to some embodiments, spacer structures 502 may be any suitable dielectric material, though preferably a different dielectric material than dielectric layer 304.

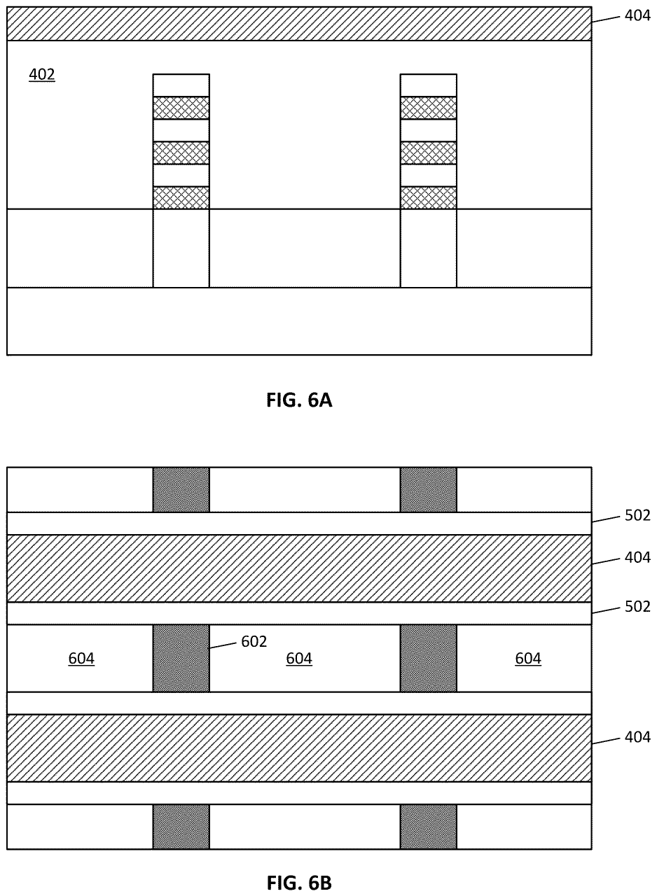

FIGS. 6A and 6B depict the cross-section and plan views of the structure shown in FIGS. 5A and 5B, respectively, following the formation of source or drain regions 602, according to some embodiments. Exposed portions of the fins between spacer structures 502 are removed. The exposed fin portions may be removed using any anisotropic etching process, such as reactive ion etching (RIE).

Once the exposed fins have been removed, source or drain regions 602 may be formed in the areas that had been previously occupied by the exposed fins between spacer structures 502. According to some embodiments, source or drain regions 602 are epitaxially grown from the exposed semiconductor material of the fins along the exterior walls of spacer structures 502. In some example embodiments, source or drain regions 602 are NMOS source or drain regions (e.g., epitaxial silicon) or PMOS source or drain regions (e.g., epitaxial SiGe).

According to some embodiments, a dielectric fill 604 is provided between adjacent source or drain regions 602. Dielectric fill 604 may be any suitable dielectric material, such as silicon oxide. In some examples, dielectric fill 604 also extends over a top surface of source or drain regions 602 (e.g., up to and planar with a top surface of spacer structures 502 and gate masking layers 404). One or more conductive contacts may be formed at a later time through dielectric fill 604 to provide electrical contact to source or drain regions 602. For the remaining figures, dielectric fill 604 is only illustrated adjacent to source or drain regions 602 so that they are visible in the plan view.

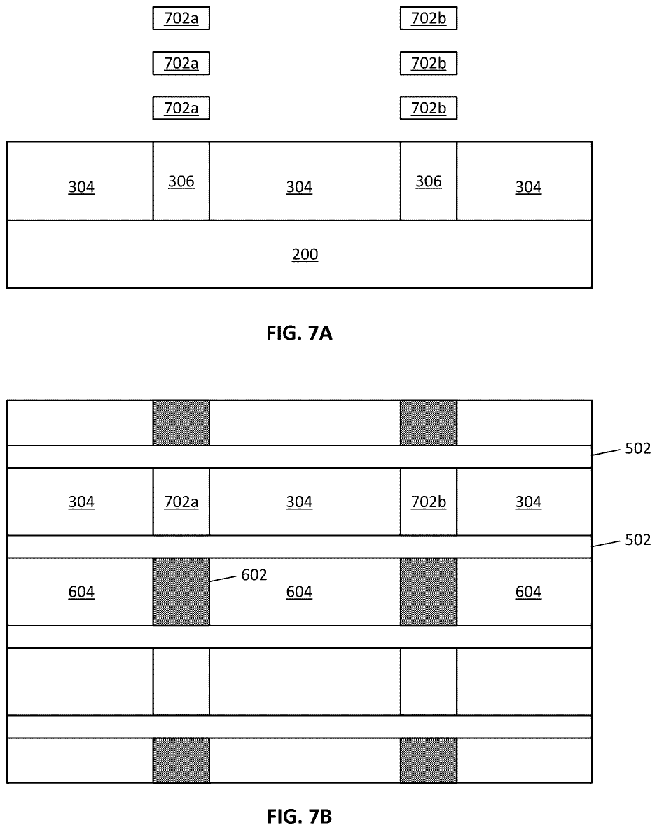

FIGS. 7A and 7B depict the cross-section and plan views of the structure shown in FIGS. 6A and 6B, respectively, following the removal of gate masking layers 404 and various sacrificial materials beneath gate masking layers 404, according to some embodiments. Once gate masking layers 404 are removed, the underlying sacrificial gate 402 is also removed thus exposing each of the fins extending between spacer structures 502.

In the example where the fins include alternating semiconductor layers, sacrificial layers 202 are selectively removed to leave behind nanoribbons 702a and 702b that extend between source or drain regions 602. The first vertical set of nanoribbons 702a represents the semiconductor region of a first semiconductor device while the second vertical set of nanoribbons 702b represents the semiconductor region of a second semiconductor device. It should be understood that nanoribbons 702a/702b may also be nanowires or nanosheets.

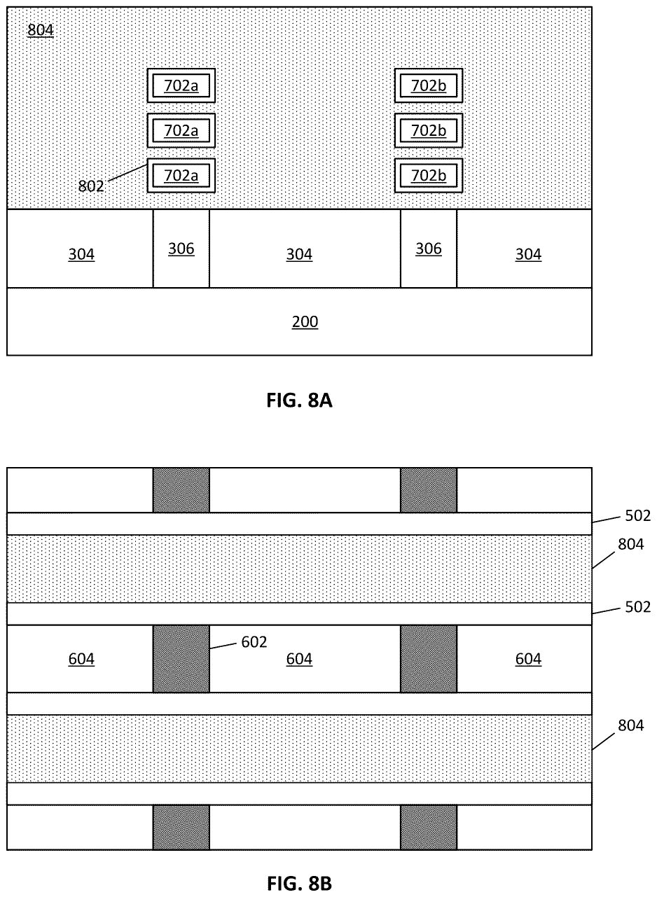

FIGS. 8A and 8B depict the cross-section and plan views of the structure shown in FIGS. 7A and 7B, respectively, following the formation of gate structures and subsequent polishing, according to some embodiments. As noted above, each gate structure includes a gate dielectric 802 and at least one conductive gate layer 804. Gate dielectric 802 may be first formed around nanoribbons 702a/702b prior to the formation of conductive gate layer 804, all of which are part of the gate structure. Gate dielectric 802 may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 802 includes a layer of hafnium oxide with a thickness between about 1 nm and about 5 nm. In some embodiments, gate dielectric 802 may include one or more silicates (e.g., titanium silicate, tungsten silicate, niobium silicate, and silicates of other transition metals). Gate dielectric 802 may include a first layer on nanoribbons 702a/702b, and a second layer on the first layer. The first layer can be, for instance, an oxide of the semiconductor material of nanoribbons 702a/702b (e.g., silicon dioxide) and the second layer can be a high-k dielectric material (e.g., hafnium oxide). According to some embodiments, gate dielectric 802 forms along all surfaces within the gate trench between spacer structures 502, such as on the top surfaces of dielectric layer 304 and subfins 306, and along inner sidewalls of spacer structures 502.

The at least one conductive gate layer 804 may be deposited using electroplating, electroless plating, CVD, PECVD, ALD, or PVD, to name a few examples. In some embodiments, gate layer 804 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate layer 804 may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

According to some embodiments, each gate structure runs orthogonally over a plurality of parallel fins or nanoribbons such that it extends over the semiconductor regions of a plurality of different semiconductor devices. Following the formation of the gate structures, the entire structure may be polished such that the top surface of the gate structures is planar with the top surface of at least spacer structures 502.

FIGS. 9A and 9B depict the cross-section and plan views of the structure shown in FIGS. 8A and 8B, respectively, following the formation of a fin cut structure 902, according to some embodiments. Fin cut structure 902 may be formed through the semiconductor region (e.g., nanoribbons 702b) of one of the semiconductor devices within the gate trench between spacer structures 502. Accordingly, in some embodiments, fin cut structure 902 abuts portions of nanoribbons 702b (e.g., a semiconductor region) within spacer structures 502. Fin cut structure 902 may interrupt both gate layer 804 along the second direction as well as the line of semiconductor devices along the first direction.

According to some embodiments, various different materials are first removed to form a recess in which to form fin cut structure 902. For example, a portion of the gate structure (e.g., gate layer 804) may first be removed using an anisotropic etch. The etching process may use gas/plasma chemistries that selectivity remove the conductive material of gate layer 804 as opposed to surrounding dielectric and/or semiconductor materials. In some other embodiments, the anisotropic etch is nonselective and removes all exposed material including gate layer 804, gate dielectric 802, nanoribbons 702b, and at least a portion of dielectric layer 304. In some other embodiments, different etch processes are carried out to selectively remove various materials within the recess. The etched recess may extend through an entire thickness of dielectric layer 304 and, in some cases, into at least a portion of the underlying substrate 200.

Once the recess has been formed, it may be filled with a dielectric material to form fin cut structure 902. According to some embodiments, fin cut structure 902 includes a low-K dielectric material, such as silicon oxide, silicon nitride, or silicon oxynitride, to name a few examples. According to some embodiments, fin cut structure 902 extends at least through a thickness of dielectric layer 304 to interrupt the subfin 306 extending in the first direction.

Since fin cut structure 902 is formed after the formation of the gate structure, gate layer 804 directly abuts along one or more sides of fin cut structure 902. Notably, gate dielectric 802 is not present between gate layer 804 and fin cut structure 902. However, it may be difficult to completely remove all materials from within the recess when forming fin cut structure 902. This is especially the case along sidewalls where thin portions of gate layer 804 may still be present. FIG. 9C illustrates the plan view from FIG. 9B with a zoomed-in look at how fin cut structure 902 may not completely extend between spacer structures 502, according to some embodiments. In the illustrated example, gate layer 804 has a sidewall portion 904 that remained behind after form the recess and thus is observable between fin cut structure 902 and spacer structure 502. In some embodiments, gate dielectric 802 may also be present along the inner sidewall of spacer structure 502.

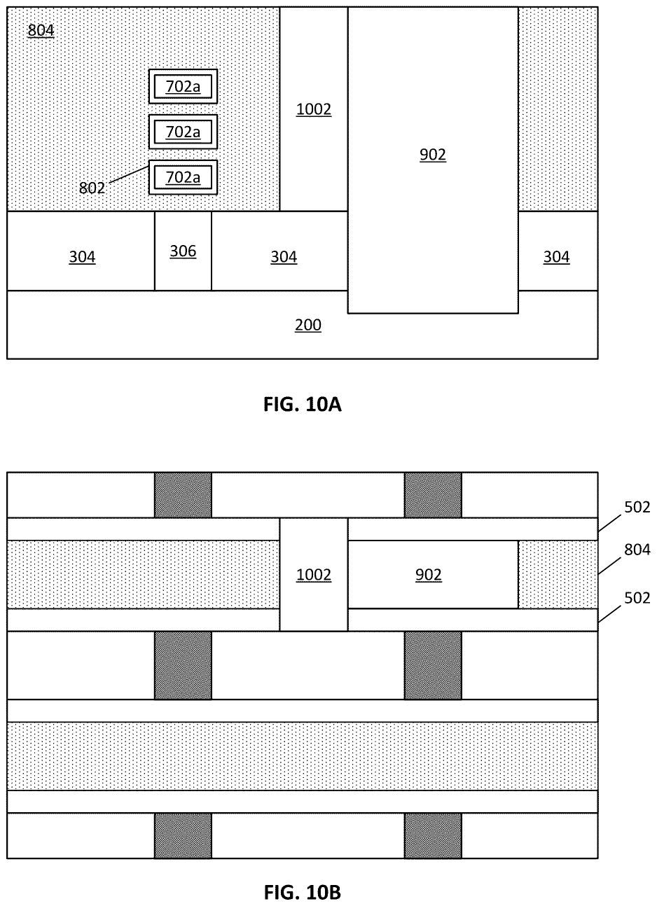

The existence of the conductive sidewall portion 904 of gate layer 804 could cause shorting problems across fin cut structure 902. Accordingly, an additional gate cut structure may be used to circumvent this issue. FIGS. 10A and 10B depict the cross-section and plan views of the structure shown in FIGS. 9A and 9B, respectively, following the formation of a gate cut structure 1002, according to some embodiments. Gate cut structure 1002 may include any suitable dielectric material such as silicon oxide, silicon nitride, or silicon oxynitride. According to some embodiments, gate cut structure 1002 is formed using a CVD process, such as ALD.

Gate cut structure 1002 may be aligned directly adjacent to fin cut structure 902 within the gate trench (such that gate cut structure 1002 abuts fin cut structure 902). In some other embodiments, a portion of gate layer 804 is between gate cut structure 1002 and fin cut structure 902. According to some embodiments, gate cut structure 1002 extends in the first direction such that it interrupts both gate layer 804 as well as one or both spacer structures 502. By extending into spacer structures 502, gate cut structure 1002 reduces (e.g., eliminates) the chance of shorting across gate cut structure 1002 via gate layer 804.

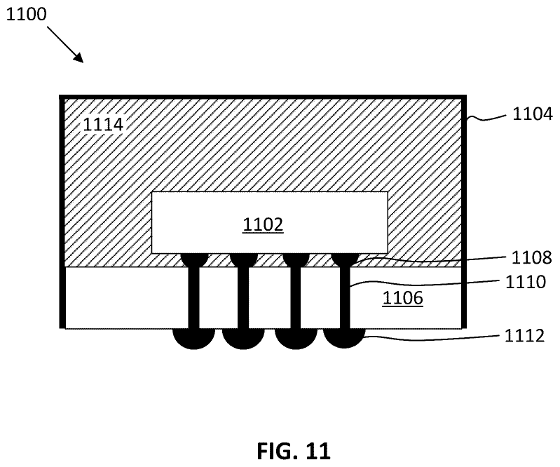

FIG. 11 illustrates an example embodiment of a chip package 1100, in accordance with an embodiment of the present disclosure. As can be seen, chip package 1100 includes one or more dies 1102. One or more dies 1102 may include at least one integrated circuit having semiconductor devices, such as any of the semiconductor devices disclosed herein. One or more dies 1102 may include any other circuitry used to interface with other devices formed on the dies, or other devices connected to chip package 1100, in some example configurations.

As can be further seen, chip package 1100 includes a housing 1104 that is bonded to a package substrate 1106. The housing 1104 may be any standard or proprietary housing, and may provide, for example, electromagnetic shielding and environmental protection for the components of chip package 1100. The one or more dies 1102 may be conductively coupled to a package substrate 1106 using connections 1108, which may be implemented with any number of standard or proprietary connection mechanisms, such as solder bumps, ball grid array (BGA), pins, or wire bonds, to name a few examples. Package substrate 1106 may be any standard or proprietary package substrate, but in some cases includes a dielectric material having conductive pathways (e.g., including conductive vias and lines) extending through the dielectric material between the faces of package substrate 1106, or between different locations on each face. In some embodiments, package substrate 1106 may have a thickness less than 1 millimeter (e.g., between 0.1 millimeters and 0.5 millimeters), although any number of package geometries can be used. Additional conductive contacts 1112 may be disposed at an opposite face of package substrate 1106 for conductively contacting, for instance, a printed circuit board (PCB). One or more vias 1110 extend through a thickness of package substrate 1106 to provide conductive pathways between one or more of connections 1108 to one or more of contacts 1112. Vias 1110 are illustrated as single straight columns through package substrate 1106 for ease of illustration, although other configurations can be used (e.g., damascene, dual damascene, through-silicon via, or an interconnect structure that meanders through the thickness of substrate 1106 to contact one or more intermediate locations therein). In still other embodiments, vias 1110 are fabricated by multiple smaller stacked vias, or are staggered at different locations across package substrate 1106. In the illustrated embodiment, contacts 1112 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1112, to inhibit shorting.

In some embodiments, a mold material 1114 may be disposed around the one or more dies 1102 included within housing 1104 (e.g., between dies 1102 and package substrate 1106 as an underfill material, as well as between dies 1102 and housing 1104 as an overfill material). Although the dimensions and qualities of the mold material 1114 can vary from one embodiment to the next, in some embodiments, a thickness of mold material 1114 is less than 1 millimeter. Example materials that may be used for mold material 1114 include epoxy mold materials, as suitable. In some cases, the mold material 1114 is thermally conductive, in addition to being electrically insulating.

### Methodology

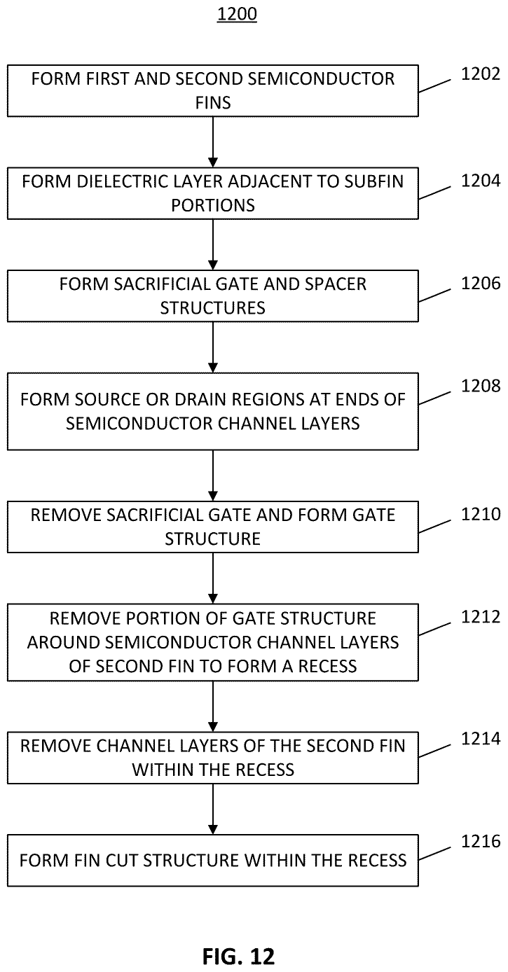

FIG. 12 is a flow chart of a method 1200 for forming at least a portion of an integrated circuit, according to an embodiment. Various operations of method 1200 may be illustrated in FIG. 2A-10A and 2B-10B. However, the correlation of the various operations of method 1200 to the specific components illustrated in the aforementioned figures is not intended to imply any structural and/or use limitations. Rather, the aforementioned figures provide one example embodiment of method 1200. Other operations may be performed before, during, or after any of the operations of method 1200. For example, method 1200 does not explicitly describe many steps that are performed to form common transistor structures. Some of the operations of method 1200 may be performed in a different order than the illustrated order.

Method 1200 begins with operation 1202 where at least first and second parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches.

Method 1200 continues with operation 1204 where a dielectric layer is formed adjacent to subfin portions of each of the first and second fins. The dielectric layer may include silicon oxide. According to some embodiments, the dielectric layer acts as an STI region between the fins and any other adjacent fins. According to some embodiments, each semiconductor device includes a subfin portion beneath a fin of alternating semiconductor layers and adjacent to the dielectric layer. The subfin may include the same material as a bulk region of the underlying semiconductor substrate.

Method 1200 continues with operation 1206 where a sacrificial gate and sidewall spacer structures are formed over both fins. The sacrificial gate may include any material that can be safely removed later in the process without etching or otherwise damaging the spacer structures and/or the fins. The sacrificial gate may include polysilicon while the spacer structures may include silicon nitride. The spacer structures are formed on sidewalls of the sacrificial gates and etched back to remove the spacer structure material from any horizontal surfaces. According to some embodiments, the fins extend lengthwise in a first direction while the sacrificial gate and spacer structures extend lengthwise in a second direction over each of the fins, the second direction being substantially orthogonal to the first direction.

Method 1200 continues with operation 1208 where source or drain regions are formed at the ends of semiconductor channel layers in each of the first and second fins. Exposed portions of the fins not covered by the sacrificial gate and sidewall spacer structures may first be removed using, for example, an RIE process. Removing the fin portions exposes ends of one or more semiconductor channel layers extending in the first direction through the sacrificial gate and sidewall spacer structures. The source or drain regions may be epitaxially grown from the exposed ends of the semiconductor layers. In the example of a PMOS device, the corresponding source or drain region may be a semiconductor material (e.g., group IV or group III-V semiconductor materials) having a higher dopant concentration of p-type dopants compared to n-type dopants. In the example of an NMOS device, the corresponding source or drain region may be a semiconductor material (e.g., group IV or group III-V semiconductor materials) having a higher dopant concentration of n-type dopants compared to p-type dopants.

Method 1200 continues with operation 1210 where sacrificial materials are removed and the gate structure is formed. The sacrificial gate may be removed using an isotropic etching process that selectively removes all of the material from the sacrificial gate, thus exposing the first and second fins between the spacer structures. In the example case where GAA transistors are used, any sacrificial layers within the exposed fins between the spacer structures are also removed to leave behind nanoribbons, nanosheets, or nanowires of semiconductor material.

The gate structure may include both a gate dielectric and a gate layer. The gate dielectric is first formed over the exposed semiconductor regions between the spacer structures followed by forming the gate layer within the remainder of the trench between the spacer structures, according to some embodiments. The gate dielectric may include any number of dielectric layers deposited using a CVD process, such as ALD. The gate layer can include any conductive material, such as a metal, metal alloy, or polysilicon. The gate layer may be deposited using electroplating, electroless plating, CVD, ALD, PECVD, or PVD, to name a few examples.

Method 1200 continues with operation 1212 where a portion of the gate structure around the semiconductor channel layers of the second fin is removed. A masking layer may be lithographically patterned over the gate structure to expose only a desired portion of the gate structure to the etching process. An anisotropic etch may be used to remove the portion of the gate layer forming a recess through at least an entire thickness of the gate layer. The etching process may use gas/plasma chemistries that selectivity remove the conductive material of the gate layer as opposed to surrounding dielectric and/or semiconductor materials. In some other embodiments, the anisotropic etch is nonselective and removes all exposed material including both the gate layer and the gate dielectric. In some other embodiments, different etch processes are carried out to selectively remove various materials within the recess. The etched recess may extend through an entire thickness of the underlying dielectric layer adjacent to the subfin portions. In some cases, the recess extends into at least a portion of the underlying substrate.

Method 1200 continues with operation 1214 where the semiconductor channel layers (e.g., nanoribbons of a GAA device) of the second fin within the recess are removed. As noted above, these layers may be removed using a separate etching process that more selectively etches the semiconductor material of the channel layers as opposed to other material types. Removing the channel layers again exposes ends of the semiconductor channel layers along the inner sides of the spacer structures.

Method 1200 continues with operation 1216 where an isolation structure (e.g., a fin cut structure) is formed within the recess. Any suitable dielectric material may be used to form the fin cut structure. According to some embodiments, the fin cut structure includes a low-K dielectric material, such as silicon oxide, silicon nitride, or silicon oxynitride, to name a few examples. According to some embodiments, the fin cut structure extends through a total thickness of the gate layer and at least through a total thickness of the dielectric layer to interrupt the subfin extending in the first direction. Since the fin cut structure is formed after the formation of the gate structure, the gate layer directly abuts along one or more sides of the fin cut structure. The gate dielectric is not present between the gate layer and the fin cut structure. The fin cut structure interrupts both the gate layer in the second direction as well as the second fin in the first direction. Accordingly, the fin cut structure also abuts the semiconductor regions from the second fin that extend within the spacer structures.

### Example System

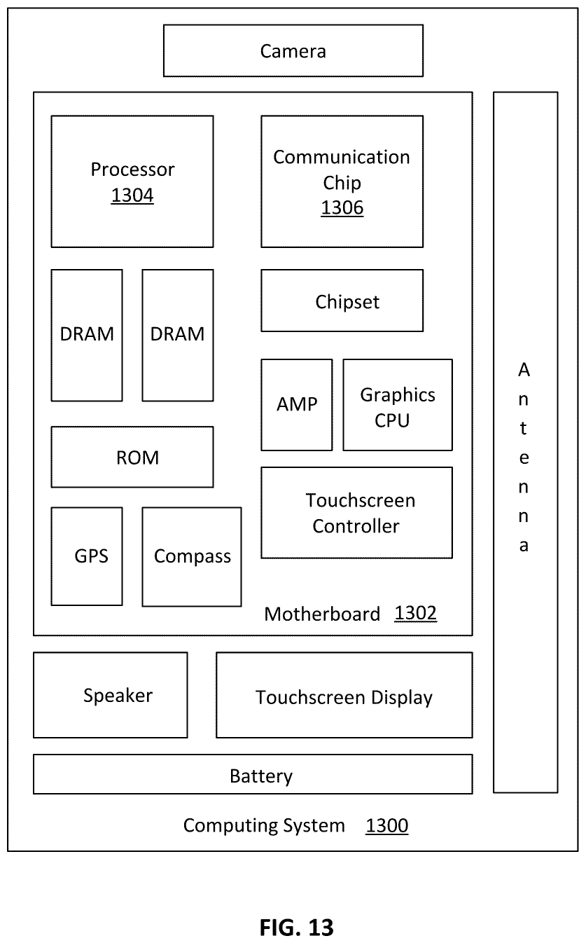

FIG. 13 is an example computing system implemented with one or more of the integrated circuit structures as disclosed herein, in accordance with some embodiments of the present disclosure. As can be seen, the computing system 1300 houses a motherboard 1302. The motherboard 1302 may include a number of components, including, but not limited to, a processor 1304 and at least one communication chip 1306, each of which can be physically and electrically coupled to the motherboard 1302, or otherwise integrated therein. As will be appreciated, the motherboard 1302 may be, for example, any printed circuit board (PCB), whether a main board, a daughterboard mounted on a main board, or the only board of system 1300, etc.

Depending on its applications, computing system 1300 may include one or more other components that may or may not be physically and electrically coupled to the motherboard 1302. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1300 may include one or more integrated circuit structures or devices configured in accordance with an example embodiment (e.g., a module including an integrated circuit device on a substrate, the substrate having one or more semiconductor devices with any number of fin cut structures, as variously provided herein). In some embodiments, multiple functions can be integrated into one or more chips (e.g., for instance, note that the communication chip 1306 can be part of or otherwise integrated into the processor 1304).

The communication chip 1306 enables wireless communications for the transfer of data to and from the computing system 1300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1306 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1300 may include a plurality of communication chips 1306. For instance, a first communication chip 1306 may be dedicated to shorter range wireless communications such as Wi-Fi and Bluetooth and a second communication chip 1306 may be dedicated to longer range wireless communications such as GPS, EDGE, GPRS, CDMA, WiMAX, LTE, Ev-DO, and others.

The processor 1304 of the computing system 1300 includes an integrated circuit die packaged within the processor 1304. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1306 also may include an integrated circuit die packaged within the communication chip 1306. In accordance with some such example embodiments, the integrated circuit die of the communication chip includes one or more semiconductor devices as variously described herein. As will be appreciated in light of this disclosure, note that multi-standard wireless capability may be integrated directly into the processor 1304 (e.g., where functionality of any chips 1306 is integrated into processor 1304, rather than having separate communication chips). Further note that processor 1304 may be a chip set having such wireless capability. In short, any number of processor 1304 and/or communication chips 1306 can be used. Likewise, any one chip or chip set can have multiple functions integrated therein.

In various implementations, the computing system 1300 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1300 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a semiconductor device having a subfin region and a first semiconductor region above the subfin region and extending in a first direction between a source region and a drain region, a dielectric layer adjacent to the subfin region, a gate structure with a gate layer comprising a conductive material, spacer layers on sidewalls of the gate structure, and an isolation structure between the spacer layers and interrupting the gate layer. The gate layer extends over the semiconductor region in a second direction different from the first direction. The isolation structure extends through at least a portion of the dielectric layer and abuts a second semiconductor region extending parallel to the first semiconductor region in the first direction. The conductive gate layer abuts at least a portion of the isolation structure.

Example 2 includes the subject matter of Example 1, wherein the first semiconductor region is a first fin comprising silicon and the second semiconductor region is a second fin comprising silicon, the first fin orientated parallel to the second fin.

Example 3 includes the subject matter of Example 1 or 2, wherein the first semiconductor region comprises a first plurality of semiconductor nanoribbons and the second semiconductor region comprises a second plurality of semiconductor nanoribbons.

Example 4 includes the subject matter of Example 3, wherein the first plurality of semiconductor nanoribbons and the second plurality of semiconductor nanoribbons comprise germanium, silicon, or a combination thereof.

Example 5 includes the subject matter of any one of Examples 1-4, wherein the isolation structure comprises silicon and nitrogen or comprises silicon and oxygen.

Example 6 includes the subject matter of any one of Examples 1-5, further comprising a gate cut adjacent to the isolation structure, wherein the gate cut interrupts the gate layer and the spacer structures.

Example 7 includes the subject matter of Example 6, wherein the gate cut comprises silicon and nitrogen or comprises silicon and oxygen.

Example 8 includes the subject matter of any one of Examples 1-7, wherein at least a portion of the gate layer is present between a sidewall of the isolation structure and one of the spacer structures.

Example 9 includes the subject matter of any one of Examples 1-8, wherein the isolation structure extends through an entire thickness of the dielectric layer.

Example 10 includes the subject matter of any one of Examples 1-9, wherein no dielectric layers are present between the gate layer and the isolation structure.

Example 11 is a printed circuit board comprising the integrated circuit of any one of Examples 1-10.

Example 12 is an electronic device including a chip package having one or more dies. At least one of the one or more dies includes a semiconductor device having a subfin region and a first semiconductor region above the subfin region and extending in a first direction between a source region and a drain region, a dielectric layer adjacent to the subfin region, a gate structure with a gate layer comprising a conductive material, spacer layers on sidewalls of the gate structure, and an isolation structure between the spacer layers and interrupting the gate layer. The gate layer extends over the semiconductor region in a second direction different from the first direction. The isolation structure extends through at least a portion of the dielectric layer and abuts a second semiconductor region extending parallel to the first semiconductor region in the first direction. The conductive gate layer abuts at least a portion of the isolation structure.

Example 13 includes the subject matter of Example 12, wherein the first semiconductor region is a first fin comprising silicon and the second semiconductor region is a second fin comprising silicon, the first fin orientated parallel to the second fin.

Example 14 includes the subject matter of Example 12, wherein the first semiconductor region comprises a first plurality of semiconductor nanoribbons and the second semiconductor region comprises a second plurality of semiconductor nanoribbons.

Example 15 includes the subject matter of Example 14, wherein the first plurality of semiconductor nanoribbons and the second plurality of semiconductor nanoribbons comprise germanium, silicon, or a combination thereof.

Example 16 includes the subject matter of any one of Examples 12-15, wherein the isolation structure comprises silicon and nitrogen or comprises silicon and oxygen.

Example 17 includes the subject matter of any one of Examples 12-16, wherein the at least one of the one or more dies further comprises a gate cut adjacent to the isolation structure, wherein the gate cut interrupts the gate layer and the spacer structures.

Example 18 includes the subject matter of Example 17, wherein the gate cut comprises silicon and nitrogen or comprises silicon and oxygen.

Example 19 includes the subject matter of any one of Examples 12-18, wherein at least a portion of the gate layer is present between a sidewall of the isolation structure and one of the spacer structures.

Example 20 includes the subject matter of any one of Examples 12-19, wherein the isolation structure extends through an entire thickness of the dielectric layer.

Example 21 includes the subject matter of any one of Examples 12-20, further comprising a printed circuit board, wherein the chip package is attached to the printed circuit board.

Example 22 includes the subject matter of any one of Examples 12-21, wherein no dielectric layers are present between the gate layer and the isolation structure.

Example 23 is a method of forming an integrated circuit. The method includes forming a first fin comprising first semiconductor material and a second fin comprising second semiconductor material, wherein the first fin and the second fin extend parallel to one another above a dielectric layer; forming a sacrificial gate layer over the first fin and the second fin and forming spacer structures on sidewalls of the sacrificial gate layer; removing the sacrificial gate layer and forming a gate structure between the sidewall layers and over the first semiconductor material and the second semiconductor material; removing a portion of the gate structure around the second semiconductor material and removing the second semiconductor material from between the spacer structures to form a recess through the gate structure; and forming an isolation structure within the recess such that the isolation structure interrupts the gate structure.

Example 24 includes the subject matter of Example 23, wherein forming the isolation structure comprises depositing a dielectric material comprising silicon and nitrogen or comprising silicon and oxygen.

Example 25 includes the subject matter of Example 23 or 24, further comprising removing at least a portion of the dielectric layer such that the recess extends into at least a portion of the dielectric layer.

Example 26 includes the subject matter of Example 25, wherein the recess extends through an entire thickness of the dielectric layer.

Example 27 includes the subject matter of any one of Examples 23-26, wherein the gate structure comprises a gate dielectric and a gate layer, and the method further comprises forming the gate dielectric around the first semiconductor material and the second semiconductor material before forming the gate layer on the gate dielectric.

Example 28 includes the subject matter of Example 27, further comprising forming a gate cut adjacent to the isolation structure, the gate cut extending through the gate layer and the sidewall layers.

Example 29 is an integrated circuit that includes a semiconductor device having a subfin region and a first semiconductor region above the subfin region and extending in a first direction between a source region and a drain region, a dielectric layer adjacent to the subfin region, a gate structure comprising a gate dielectric and a gate layer, spacer structures on sidewalls of the gate structure, and an isolation structure between the spacer structures and interrupting the gate layer. The gate layer comprises a conductive material and extends over the semiconductor region in a second direction different from the first direction. The isolation structure extends through at least a portion of the dielectric layer and abuts a second semiconductor region extending parallel to the first semiconductor region in the first direction. At least a portion of the gate layer is present between a sidewall of the isolation structure and one of the spacer structures.

Example 30 includes the subject matter of Example 29, wherein the first semiconductor region is a first fin comprising silicon and the second semiconductor region is a second fin comprising silicon, the first fin orientated parallel to the second fin.

Example 31 includes the subject matter of Example 29, wherein the first semiconductor region comprises a first plurality of semiconductor nanoribbons and the second semiconductor region comprises a second plurality of semiconductor nanoribbons.

Example 32 includes the subject matter of Example 31, wherein the first plurality of semiconductor nanoribbons and the second plurality of semiconductor nanoribbons comprise germanium, silicon, or a combination thereof.

Example 33 includes the subject matter of any one of Examples 29-32, wherein the isolation structure comprises silicon and nitrogen or comprises silicon and oxygen.

Example 34 includes the subject matter of any one of Examples 29-33, further comprising a gate cut adjacent to the isolation structure, wherein the gate cut interrupts the gate layer and the spacer structures.

Example 35 includes the subject matter of Example 34, wherein the gate cut comprises silicon and nitrogen or comprises silicon and oxygen.

Example 36 includes the subject matter of any one of Examples 29-35, wherein the isolation structure extends through an entire thickness of the dielectric layer.

Example 37 is a printed circuit board comprising the integrated circuit of any one of Examples 29-36.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit structure, comprising:
a first fin over a first subfin;
a second fin over a second subfin, the second fin laterally spaced apart from the first fin;
a trench isolation adjacent to the first subfin and the second subfin;
a first gate dielectric over the first fin and the second fin, and the first gate dielectric on the trench isolation;
a first gate layer over the first gate dielectric;
a gate cut structure laterally spaced apart from the second fin, the gate cut structure in contact with the first gate layer;
a fin cut structure laterally adjacent to the gate cut structure and the trench isolation, the fin cut structure having a bottom surface below a top surface of the trench isolation;
a third fin over a third subfin, the third fin laterally spaced apart from the fin cut structure, and the third subfin adjacent to the trench isolation, wherein the gate cut structure is laterally between the second fin and the fin cut structure, and the fin cut structure is laterally between the gate cut structure and the third fin;
a second gate dielectric over the third fin and on the trench isolation; and
a second gate layer over the second gate dielectric.

2. The integrated circuit structure of claim 1, wherein the gate cut structure has an uppermost surface at a same level as an uppermost surface of the first gate layer.

3. The integrated circuit structure of claim 1, wherein the gate cut structure has an uppermost surface at a same level as an uppermost surface of the fin cut structure.

4. The integrated circuit structure of claim 1, wherein the fin cut structure is in contact with the gate cut structure.

5. The integrated circuit structure of claim 1, wherein the fin cut structure is in contact with the second gate layer.

6. The integrated circuit structure of claim 1, wherein there are no intervening fins between the second fin and the third fin.

7. The integrated circuit structure of claim 1, wherein the gate cut structure has a width greater than a width of the fin cut structure along a direction orthogonal to a direction from the second fin to the third fin.

8. An integrated circuit structure, comprising:
a first fin over a first subfin;
a second fin over a second subfin, the second fin laterally spaced apart from the first fin;
a trench isolation adjacent to the first subfin and the second subfin;
a first gate dielectric over the first fin and the second fin, and the first gate dielectric on the trench isolation;
a first gate layer over the first gate dielectric;
a first dielectric structure laterally spaced apart from the second fin, the first dielectric structure in contact with the first gate layer;
a second dielectric structure laterally adjacent to the first dielectric structure and the trench isolation, the second dielectric structure having a bottom surface below a top surface of the trench isolation, and the second dielectric structure distinct from the first dielectric structure;
a third fin over a third subfin, the third fin laterally spaced apart from the second dielectric structure, and the third subfin adjacent to the trench isolation, wherein the first dielectric structure is laterally between the second fin and the second dielectric structure, and the second dielectric structure is laterally between the first dielectric structure and the third fin;
a second gate dielectric over the third fin and on the trench isolation; and
a second gate layer over the second gate dielectric.

9. The integrated circuit structure of claim 8, wherein the first dielectric structure has an uppermost surface at a same level as an uppermost surface of the first gate layer.

10. The integrated circuit structure of claim 8, wherein the first dielectric structure has an uppermost surface at a same level as an uppermost surface of the second dielectric structure.

11. The integrated circuit structure of claim 8, wherein the second dielectric structure is in contact with the first dielectric structure.

12. The integrated circuit structure of claim 8, wherein there are no intervening fins between the second fin and the third fin.

13. The integrated circuit structure of claim 8, wherein the first dielectric structure has a width greater than a width of the second dielectric structure along a direction orthogonal to a direction from the second fin to the third fin.

14. A method of fabricating an integrated circuit structure, the method comprising:
forming a first fin over a first subfin;
forming a second fin over a second subfin, the second fin laterally spaced apart from the first fin;
forming a trench isolation adjacent to the first subfin and the second subfin;
forming a first gate dielectric over the first fin and the second fin, and the first gate dielectric on the trench isolation;
forming a first gate layer over the first gate dielectric;
forming a gate cut structure laterally spaced apart from the second fin, the gate cut structure in contact with the first gate layer;
forming a fin cut structure laterally adjacent to the gate cut structure and the trench isolation, the fin cut structure having a bottom surface below a top surface of the trench isolation;
forming a third fin over a third subfin, the third fin laterally spaced apart from the fin cut structure, and the third subfin adjacent to the trench isolation, wherein the gate cut structure is laterally between the second fin and the fin cut structure, and the fin cut structure is laterally between the gate cut structure and the third fin;
forming a second gate dielectric over the third fin and on the trench isolation; and
forming a second gate layer over the second gate dielectric.

15. The method of claim 14, wherein the gate cut structure has an uppermost surface at a same level as an uppermost surface of the first gate layer.

16. The method of claim 14, wherein the gate cut structure has an uppermost surface at a same level as an uppermost surface of the fin cut structure.

17. The method of claim 14, wherein the fin cut structure is in contact with the gate cut structure.

18. The method of claim 14, wherein the fin cut structure is in contact with the second gate layer.

19. The method of claim 14, wherein there are no intervening fins between the second fin and the third fin.

20. The method of claim 14, wherein the gate cut structure has a width greater than a width of the fin cut structure along a direction orthogonal to a direction from the second fin to the third fin.

21. An integrated circuit structure, comprising:
a first plurality of nanowires over a first subfin;
a second plurality of nanowires over a second subfin, the second plurality of nanowires laterally spaced apart from the first plurality of nanowires;
a trench isolation adjacent to the first subfin and the second subfin;
a first gate dielectric over and around the first plurality of nanowires and the second plurality of nanowires, and the first gate dielectric on the trench isolation;
a first gate layer over and around the first gate dielectric;
a gate cut structure laterally spaced apart from the second plurality of nanowires, the gate cut structure in contact with the first gate layer;
a fin cut structure laterally adjacent to the gate cut structure and the trench isolation, the fin cut structure having a bottom surface below a top surface of the trench isolation;
a third plurality of nanowires over a third subfin, the third plurality of nanowires laterally spaced apart from the fin cut structure, and the third subfin adjacent to the trench isolation, wherein the gate cut structure is laterally between the second plurality of nanowires and the fin cut structure, and the fin cut structure is laterally between the gate cut structure and the third plurality of nanowires;
a second gate dielectric over and around the third plurality of nanowires and on the trench isolation; and
a second gate layer over and around the second gate dielectric.

22. The integrated circuit structure of claim 21, wherein the gate cut structure has an uppermost surface at a same level as an uppermost surface of the first gate layer.

23. The integrated circuit structure of claim 21, wherein the gate cut structure has an uppermost surface at a same level as an uppermost surface of the fin cut structure.

24. The integrated circuit structure of claim 21, wherein the fin cut structure is in contact with the gate cut structure.

25. The integrated circuit structure of claim 21, wherein the fin cut structure is in contact with the second gate layer.

26. The integrated circuit structure of claim 21, wherein there are no intervening nanowires between the second plurality of nanowires and the third plurality of nanowires.

27. The integrated circuit structure of claim 21, wherein the gate cut structure has a width greater than a width of the fin cut structure along a direction orthogonal to a direction from the second plurality of nanowires to the third plurality of nanowires.
